(19) United States
(12) Patent Application Publication
(10) Pub. No.: US 2024/0159678 A1
(43) Pub. Date: May 16, 2024

(54) METHOD AND APPARATUS FOR DETECTION OF RADICAL SPECIES

(71) Applicant: Yissum Research Development Company of the Hebrew University of Jerusalem Ltd., Jerusalem (IL)

(72) Inventors: Nir BAR-GILL, Tel-Aviv (IL); Yoav NINIO, Jerusalem (IL); Uri BANIN, Mevasseret Zion (IL); Nir WAISKOPF, Jerusalem (IL)

(73) Assignee: Yissum Research Development Company of the Hebrew University of Jerusalem Ltd., Jerusalem (IL)

(21) Appl. No.: 18/549,192

(22) PCT Filed: Mar. 10, 2022
(86) PCT No.: PCT/IL2022/050275

§ 371 Date: Sep. 6, 2023

Related U.S. Application Data
(60) Provisional application No. 63/159,099, filed on Mar. 10, 2021.

(51) Int. Cl. G01N 21/64

(52) U.S. Cl. CPC G01N 21/6486; G01N 2021/6419

(57) ABSTRACT

A non-magnetic method is disclosed for determining presence and/or concentration of at least one radical species in a sample.

### TECHNOLOGICAL FIELD

The invention generally contemplates method and apparatus for detecting radicals in general and specifically reactive oxygen species (ROS).

### BACKGROUND OF THE INVENTION

Radicals are reactive molecules that contain unpaired electrons. Reactive Oxygen Species (ROS) are chemically reactive molecules containing oxygen. ROS are quite ubiquitous, participating in various catalytic processes, as well as in biochemical reactions and cellular signaling, including pathological situations such as cancer, cardio-vascular pathologies and autoimmune diseases. Due to their importance, the ability to determine presence and characterize ROS with high sensitivity and spatial resolution provides insights into the local dynamics of various processes in chemistry and biology.

The presence of unpaired spins in ROS generates magnetic noise which can be detected using proximal magnetic sensors. However, due to their highly reactive nature, the lifetime of the magnetic noise is relatively short, usually on the order of a few μs, making such measurements difficult. Current methods constituting state-of-the-art for detecting ROS, such as spectrophotometry and chemiluminescence, rely on processes in which they create stable labels. Using these methods, it is possible to measure radical concentrations down to

$$3 \times {10}^{- 13} \frac{M}{\sqrt{H} z} .$$

Despite the high sensitivity of these methods, they are designed for relatively large volumes, and thus are also limited in their ability to provide spatial information on the radical concentration.

In recent years, diamond nitrogen-vacancy (NV) centers have emerged as useful magnetic sensors, due to their unique spin and optical properties. The NV center is a color defect in the diamond lattice, comprising the combination of a carbon vacancy and an adjacent nitrogen atom. As illustrated in FIG. 1, the NV center can be found in two charged states: neutral NV⁰ and negative NV⁻ states, which have different emission spectra. NV-based magnetic noise measurements have been demonstrated in various contexts, essentially performing relaxometry, i.e., monitoring the effect of magnetic field fluctuations on the NV relaxation time [1-3]. Previous work focusing on characterizing spin concentrations through relaxometry was mostly based on Gadolinium (+3), a common MRI contrast agent with spin 7/2, which produces characteristic magnetic fluctuations that can reduce the T₁ relaxation time by more than 90%.

### BACKGROUND PUBLICATIONS

[1] Kaufmann, S.; Simpson, D. A.; Hall, L. T.; Perunicic, V.; Senn, P.; Steinert, S.; McGuinness, L. P.; Johnson, B. C.; Ohshima, T.; Caruso, F.; Wrachtrup, J.; Scholten, R. E.; Mulvaney, P.; Hollenberg, L. Detection of atomic spin labels in a lipid bilayer using a single-spin nanodiamond probe. Proceedings of the National Academy of Sciences 2013, 110, 10894.

[2] Steinert, S.; Ziem, F.; Hall, L. T.; Zappe, A.; Schweikert, M.; Gotz, N.; Aird, A.; Balasubramanian, G.; Hollenberg, L.; Wrachtrup, J. Magnetic spin imaging under ambient conditions with sub-cellular resolution. Nature Communications 2013, 4, 1607.

[3] McCullian, B. A.; Thabt, A. M.; Gray, B. A.; Melendez, A. L.; Wolf, M. S.; Safonov, V. L.; Pelekhov, D. V.; Bhallamudi, V. P.; Page, M. R.; Hammel, P. C. Broadband multi-magnon relaxometry using a quantum spin sensor for high frequency ferromagnetic dynamics sensing. Nature Communications 2020, 11, 5229.

### GENERAL DESCRIPTION

The inventors of the technology disclosed herein have developed a novel non-magnetic, optical sensing approach for detection and quantification of radical concentrations with high spatial resolution. Methods of the invention may be utilized for in situ detection of radical formation, over long periods of time, with high sensitivity and without needing to replenish or rejuvenate the sensor at any stage. Also, the methods enable local and/or spatially resolved detection of the presence and concentration of radicals with high signal to noise ratio, enabling a sensitivity to radical concentrations at the level of 10 nM/√Hz.

In most general terms, the method includes measuring a change in the rate of fluorescence emission from diamond NV centers due to the presence of radicals. The measurement may follow any time pattern: it may be continuous over a predetermined period of time, at specific predefined intervals, randomly or periodically, at specific time points, or at any other time or time pattern as desired.

Thus, in a first of its aspects the invention provides a non-magnetic method for determining presence and/or concentration of at least one radical species, e.g., reactive oxygen species (ROS), in a sample, the method comprising exciting at least one nitrogen vacancy (NV) center in a diamond having at least one near-surface NV center, while the diamond is in contact with a sample containing or suspected of containing the at least one radical species and measuring fluorescence emitted from the at least one NV center in response to said excitation.

The invention further provides a non-magnetic method for determining presence and/or concentration of at least one radical species in a sample, the method comprising contacting the sample with a surface region of a diamond having at least one near-surface nitrogen vacancy (NV) center, exciting said at least one NV center while the diamond is in contact with the sample and measuring fluorescence emitted from the at least one NV center in response to the excitation.

The invention further provides a non-magnetic method for determining presence and/or concentration of at least one radical species, e.g., ROS, in a sample, the method comprising contacting a sample suspected of containing the at least one radical species with a surface region of a diamond having least one near-surface NV center, irradiating the diamond with a primary radiation, and measuring fluorescence emission from said at least one NV center.

In some embodiments, in a method of the invention, presence and/or concentration of the at least one radical species is achievable by comparing (i) fluorescence emission from a control diamond sample being either an NV-containing diamond not in the presence of radicals, or diamond having NV centers that are present deep within the diamond (namely centers that are not shallow, as defined, or which are present at depths that are greater than 15 nm) and thus are unaffected by radicals outside of the diamond, with (ii) fluorescence emission from a diamond containing the at least one near-surface NV center when in contact with a sample containing radical species. A difference in the emission between the control diamond sample and the tested sample ((i) as compared to (ii) above) provides an indication of (or indicates) presence of the radical species in the sample. Concentration of the radical species may be determined as detailed further below.

Further provided by the present disclosure is a method for determining a change in a rate of fluorescence emission from a diamond having at least one near-surface NV center, the method comprising irradiating the diamond prior and subsequent to contacting the at least one NV center with a sample containing or suspected of containing at least one radical species, e.g., ROS, measuring the rate of fluorescence emitted from said at least one NV center following excitation of the at least one center (prior to and subsequent to contacting) and determining the change in the rate.

According to the present disclosure, the change in the emission rate may be determined by:
measuring the rate of fluorescence emitted from the diamond NV center(s) following excitation prior to contacting the diamond NV center(s) with the sample containing or suspected of containing the at least one radical species;
measuring the rate of fluorescence emitted from the diamond NV center(s) following excitation after (or subsequent to) contacting the diamond NV center(s) with the sample containing or suspected of containing at least one radical species; and
determining the change in the rates (i.e., prior to versus subsequent to contacting with the sample);

wherein a decrease in NV⁻ fluorescence emission rate and/or increase in NV⁰ fluorescence emission rate provides an indication of presence of the at least one ROS in the sample.

In some embodiments, measuring the rate of fluorescence emitted from the diamond NV center(s) prior to or after contacting with the sample comprises separately or simultaneously measuring rate of emission from NV⁻ centers and/or measuring rate of emission from NV⁰ centers.

In some embodiments, the change in the emission rate is determined by:
measuring the rate of fluorescence emitted from the diamond NV center(s) comprising NV⁻ and NV⁰ centers following excitation prior to contacting the diamond NV center(s) with the sample containing or suspected of containing the at least one radical species;
measuring the rate of fluorescence emitted from the diamond NV center(s) comprising NV⁻ and NV⁰ centers following excitation after contacting the diamond NV center(s) with the sample containing or suspected of containing at least one radical species; and
determining the change in the NV⁻ fluorescence emission rate and/or in the NV⁰ fluorescence emission rate;

wherein a decrease in the NV⁻ fluorescence emission rate and/or an increase in the NV⁰ fluorescence emission rate provides an indication of presence of the at least one radical species in the sample.

The “diamond” sample utilized in methods and systems of the invention is a single or a plurality of diamonds, each having one or more nitrogen vacancy (NV) center. The diamond may be selected from bulk diamonds, diamond membranes, nano-diamonds, micro-diamonds, synthetic diamonds, natural diamonds, and any diamond structure including at least one NV center.

In some embodiments, the diamond is an unfunctionalized diamond, namely a diamond that has no surface functionalization. In some embodiments, the diamond fluorescence is not derived or due to surface functionalization. In some embodiments, the diamond is free of surface functionalization that is selected to interact with the radical species. As used herein, ‘surface functionalization’ refers to any ligand or group that is covalently or otherwise made to associate with a surface region of the diamond. Such functionalization is excluded irrespective of its chemical composition. The term ‘surface functionalization’ does not encompass surface groups or atoms naturally present on the surface of the diamond or such groups or atoms which are present following diamond treatment for creating the NV centers.

In some embodiments, the diamond is a nanodiamond.

The “at least one NV center” embedded in the diamond is one or more, typically a plurality, of color centers, which comprise a nitrogen atom next to a carbon vacancy. The nitrogen atom, which may be located within the diamond crystal lattice is covalently bonded to three carbon atoms. The NV centers can occur naturally within the diamond or can be created using N³⁰ ion implantation or in nitrogen rich diamonds by electron irradiation which creates vacancies in the diamond and subsequent annealing which causes the vacancies to migrate towards the nitrogen atoms to produce an NV center. When the NV centers are optically excited by light generated by an illumination source (primary radiation), via a single or multiple photon process, electron excitation occurs from the ground state (³A) of the NV centers to their excited state (³E). The excitation (by irradiation or illumination) can be performed from any angle with respect to the NV centers, e.g., from the top or from above the diamond sample. An additional illumination/excitation process may be used in order to excite the electrons of the NV centers from ¹E to ¹A energy level. This additional step may be carried out to increase the number of emitted photons and improve the readout fidelity and single-to-noise ratio (SNR). The additional excitation may be via the same or different illumination source, as described herein.

Methods of the invention are non-magnetic methods. In other words, they do not involve magnetic measurements of any sort; rather methods of the invention determine presence and concentration of radical species by optical means, e.g., by determining a fluorescence emission profile, as disclosed herein. Alternatively, methods of the invention may be regarded fully optical, excluding any non-optical step.

Following excitation of the at least one NV center (e.g., by means of illumination), fluorescence is emitted (radiation response or fluorescence emission) from the sample (usually due to the decay from the ³E energy levels) and may thus be measured. The emitted photons (fluorescence) are collected and counted by a photon counter positioned at any angle in relation to the NV centers, thereby enabling both qualitative and quantitative measurements. Thus, “measuring fluorescence emission” or ‘measuring fluorescence emitted in response to excitation’ includes both qualitative and quantitative measurements. In some embodiments, the emission is measured by means disclosed herein and used to determine presence of the radical species, e.g., ROS in a sample. In other embodiments, the emission is measured and used to quantify the amount or concentration of the radical species present in a sample.

As demonstrated in FIG. 1, the NV centers can be found in two charged states: neutral NV⁰ state and negative NV⁻ state, which have different emission spectra. Detection and quantification of radical concentrations, with high spatial resolution, is enabled by the presence of the two charged states or by the centers ability to move between the states in response to electron transfer. The presence of radicals provides a pathway for electron transfer, thus affecting or modifying a fluorescence rate associated with each of the charged states. Accordingly, presence of radicals causes a decrease the NV⁻ fluorescence rate and an increase the NV⁰ fluorescence rate.

In some embodiments, emission is measured prior and subsequent to contacting the NV center(s) with a sample containing or suspected of containing the radical species.

In some embodiments, measuring fluorescence emission includes (comprising or consisting) measuring a fluorescence emission profile. The emission profile includes fluorescence rate, total number of fluorescence photons emitted, spectral distribution of the emission, duration of emission, etc. In some embodiments, measuring fluorescence emission includes measuring emission rate.

In some embodiments, measuring the rate of fluorescence emitted from the diamond NV center(s) prior to or after contacting with the sample comprises measuring rate of emission from the NV⁻ centers and/or measuring rate of emission from the NV⁰ centers.

According to the present disclosure, the change in the emission rate may be determined by:
measuring the rate of fluorescence emitted from the diamond NV⁻ center(s) and/or measuring the rate of emission from the diamond NV⁰ center(s) following irradiation and prior to contacting the diamond NV center(s) with the sample containing or suspected of containing the at least one radical species;
measuring the rate of fluorescence emitted from the diamond NV⁻ center(s) and/or measuring the rate of emission from the diamond NV⁰ center(s) following (or subsequent to) irradiation and after contacting the diamond NV center(s) with the sample containing or suspected of containing at least one radical species; and
determining the change in the rate (or whether the rates are different);

wherein a decrease in NV⁻ fluorescence emission rate and/or increase in NV⁰ fluorescence emission rate provides an indication of presence of the at least one radical species in the sample.

As stated herein, the at least one NV center (or NV center(s)) is a “near-surface” NV center. In other words, the NV center is present at shallow depths, typically between 1 and 15 nm from the diamond surface. Shallow NVs are sensitive to variations in the charge state of the diamond surface, and therefore respond to the presence of radicals in their vicinity through a change in the fluorescence properties as described herein.

Deep NV centers or NV centers that are not shallow are present at depths greater than 15 nm from the diamond surface.

In some embodiments, the diamond comprises a plurality of NV centers.

In some embodiments, the diamond contains a quasi-2D layer of NV centers created through ion implantation and annealing.

In some embodiments, the diamond contains a quasi-2D layer of NV centers with a density of between 1 and 600 NVs per μm².

In some embodiments, the diamond contains NV centers in a density of between 1 and 600 NVs per μm².

In some embodiments, the diamond contains a quasi-2D layer of NV centers at a mean depth of between 1 and 15 nm. In some embodiments, the mean depth is between 10 and 15 nm. In some embodiments, the mean depth is 1, 2, 3, 4, 5, 6, 7, 8, 9, 10, 11, 12, 13, 14 or 15 nm from the diamond surface.

In some embodiments, the diamond contains a quasi-2D layer of NV centers with a density of between 1 and 600 NVs per pm 2 at a mean depth of between 1 and 15 nm.

In some embodiments, the diamond contains a plurality of NV centers with a density of between 1 and 600 NVs per pm 2 at a mean depth of between 1 and 15 nm.

In some embodiments, the NV centers are present at a density of between 1 and 10, 1 and 20, 1 and 30, 1 and 40, 1 and 50, 1 and 60, 1 and 70, 1 and 80, 1 and 90, 1 and 100, 1 and 110, 1 and 120, 1 and 130, 1 and 140, 1 and 150, 1 and 160, 1 and 170, 1 and 180, 1 and 190, 1 and 200, 10 and 30, 10 and 40, 10 and 50, 10 and 60, 10 and 70, 10 and 80, 10 and 90, 10 and 100, 10 and 110, 10 and 120, 10 and 130, 10 and 140, 10 and 150, 10 and 160, 10 and 170, 10 and 180, 10 and 190, 10 and 200, 50 and 100, 50 and 150, 50 and 200, 50 and 250, 50 and 300, 50 and 350, 50 and 400, 50 and 450, 50 and 500, 50 and 550, 50 and 600, 100 and 200, 100 and 250, 100 and 300, 100 and 350, 100 and 400, 100 and 450, 100 and 500, 100 and 550, 100 and 600, 200 and 300, 200 and 400, 200 and 500, 200 and 600, 300 and 400, 300 and 400, 300 and 500, 300 and 600, 400 and 500, or 500 and 600 NVs per μm².

As noted, the NV center(s) are optically excited by light generated by an illumination source, via a single or multiple photon process. Thus, a method of the invention may provide determining presence and/or concertation of at least one radical species in a sample by:
exciting (or irradiating or illuminating) a diamond near-surface NV centers by an excitation source capable of exciting the NV center(s); and
detecting photons emitted from the NV centers.

In some embodiments, the excitation source is a light source illuminating the diamond sample at a preselected wavelength, e.g., between 380 and 638 nm, or between 380 and 480 nm. In some embodiments, the wavelength is between 400 and 480 nm.

In some embodiments, the excitation source comprises at least one illumination source. In some embodiments, the excitation source comprises at least two illumination sources.

In some embodiments, each of the at least two illumination sources is configured or selected to independently generate light of a wavelength between 380 and 638 nm. In some embodiments, the two illumination sources comprise a green laser and a blue laser.

In some embodiments, a method of the invention for determining presence and concentration of the at least one radical species in a sample comprises applying an optical excitation radiation to the diamond having at least one NV center, the radiation comprising green light and/or blue light.

In some embodiments, a method of the invention for determining presence and concentration of the radical species in a sample comprises irradiating the diamond with at least two light sources, each independently generating light of a wavelength between 380 or 400 and 638 nm.

In some embodiments, a method of the invention for determining presence and concentration of the radical species in a sample comprises irradiating the diamond with a green laser and a blue laser, wherein blue laser irradiation/illumination is over a period of time shorter than the time period of the green laser irradiation/illumination.

In some embodiments, in a method of the invention the diamond is irradiated or illuminated by a green laser for a period of time and simultaneously irradiated or illuminated with a blue laser for a shorter period of time.

In some embodiments, in a method of the invention
irradiating the diamond with a green laser for a period of time;
irradiating the diamond with a blue laser while irradiation with a green laser continues;
ceasing irradiation with the blue laser and measuring fluorescence emission after a time period from the ceasing of the irradiation, while irradiation with the green laser continues.

In order to distinguish between the NV⁻ fluorescence and the NV⁰ fluorescence, a high pass filter (cut-off frequency=650 nm) and a band pass filter (575-625 nm), respectively, may be used. Thus, in some embodiments, in a method of the invention, fluorescence emission from NV⁻ centers and from NV⁰ centers are separately measured.

In some embodiments, the NV⁻ fluorescence is measured via a filter having a cut-off frequency of or around 650nm.

In some embodiments, the NV⁰ fluorescence is measured via a filter having a cut off frequency between 575 and 625 nm.

Detection of photons emitted from the NV center(s) comprises detecting spin-dependent fluorescence (NV⁻ vs NV⁰ of wavelengths between 575 and 900 nm, wherein the emission band of the NV⁰ charge state covers a range of 575-850 nm and of the NV⁻ charge state covers a range of 638-900 nm.

In some embodiments, the method comprises irradiating a diamond having near-surface NV center(s) by a light having a wavelength between 360 and 638 nm; and detecting photons emitted from the NV center(s).

In some embodiments, the fluorescence measurement is conducted during a period of time τ.

In some embodiments, the time period t is between 100 ns-10 ms.

In some embodiments, the diamond is point-illuminated. In other words, a preselected spot at a certain depth of the diamond is illuminated and excited.

In some embodiments, detection is via a pinhole provided in an optical conjugate plane in front of a detector, e.g., to eliminate out-of-focus emission signals.

Samples containing the radical species, e.g., reactive oxygen species (ROS) or suspected of containing same may be any liquid (solution) samples containing the radical species or a material which can decompose to provide the radical species in solution. Typically, the sample is an aqueous sample, yet in some cases it may be an organic or a non-aqueous sample containing the radical species or a material that can decompose to provide the radical species.

The radical species may be formed in situ, e.g., by illumination or irradiation (or any other process), once the sample is brought into contact with the diamond NV centers or may be present in the sample prior to contacting with the diamond. In some cases, the presence and/or amount (concentration) of the radical species in the sample is unknown. Thus, to qualitatively and quantitatively determine presence of the radical species, the sample may be evaluated utilizing methods and apparatuses provided herein, which enable direct probing and spatial mapping of radical formation and dynamics in fields such as material science and chemistry, for example for studying radical related degradation (e.g., in batteries); in biology, for example in providing high resolution mapping and tracking of radical-mediated intracellular signal transduction and cellular signaling, or for monitoring of radical-involved processes; and in other fields, thereby providing valuable information on the origin, propagation and functioning of radical in various systems.

The radical species are typically in a form of an atom or group of atoms that have one or more unpaired electrons. The radical species may be derived from any atom, such as oxygen, sulfur, carbon and hydrogen atoms, or from any group of atoms containing at least one such atom. Other atom radicals may be similarly suitable. When the radicals are derived from oxygen atoms, reactive oxygen species (ROS) are obtained. The ROS species may be in a variety of forms, or mixtures of such forms, e.g., in the form of a superoxide anion, as peroxide, a hydroxyl radical and mixtures thereof.

Also provided by the herein disclosure is a device comprising a diamond as defined herein. Devices of the invention may be provided as hand-held diagnostic devices or as stationary devices and are aimed to determine presence and/or amount of at least one radical species in a sample. In its construction, a device of the invention is configured and operable to provide a continuous and real-time evaluation of an emission profile relating to or derived from presence of radical species in a sample; namely the device enables determining and reporting presence of the radical species, formation of the radical species, changes in radical species concentration, real-time change in radical concentration, etc.

A device of the invention comprises a diamond sample holder for a diamond comprising at least one or a plurality of NV centers, a primary excitation source configured and operable to excite the NV center(s), a fluorescence detector and optionally at least one wavelength filter configured and operable to distinguish between fluorescence emission from NV⁻ centers and fluorescence emission from NV⁰ centers.

In some embodiments, the device comprises
the diamond sample holder,
the primary excitation source,
the fluorescence detector, and
the at least one wavelength filter configured and operable to distinguish between fluorescence emission from NV⁻ centers and fluorescence emission from NV⁰ centers.

In some embodiments, device is provided with a diamond sample in the holder.

In some embodiments, the primary excitation source is a light source configured for illuminating the diamond sample at a preselected wavelength, e.g., between 360 and 638 nm.

In some embodiments, the light source is positioned to point-illuminate a preselected spot at a (predefined) depth of the diamond.

In some embodiments, detection is via a pinhole provided in an optical conjugate plane in front of the detector to eliminate out-of-focus emission signals.

In some embodiments, the light source is configured to provide spatial scanning of two or more spots of the diamond NV center(s).

The spin states of the NV centers can be read out by monitoring the spin-dependent fluorescence in the 500 to 1000 nm range when the spins relax from the excited state via a spin-conserving path. The high refractive index of diamond results in a small critical angle at the diamond-air interface. As most of the fluorescence escapes from the side faces of the diamond after many total reflections, a microscope objective is used for collecting fluorescence from the NV centers. In some embodiments, a device according to the present disclosure is arranged or structured as a confocal device or a microscope.

As used herein, the “confocal arrangement” or device offers several advantages over methodologies used thus far for determining presence of radical species in a sample. Such advantages include, inter alia, the ability to control depth of field, elimination or reduction of background information away from the focal plane (that can lead to image degradation), and the ability to collect serial optical sections from the diamond sample.

In the confocal arrangement, a light source configured to provide illumination of a selected wavelength, e.g., laser, is focused onto a defined spot at a specific depth within the diamond. This leads to the emission of fluorescent light at the illumination spot. A confocal pinhole in the optical pathway cuts off signals that are out of focus, thus allowing only the fluorescence signals from the illuminated spot to enter the light detector. Thus, in the confocal arrangement implemented in a device of the invention, the device comprises an illumination source and a detector, both arranged such that the illumination and detection light paths share a common focal plane, achievable by a pinhole positioned at a distance from the diamond. The illumination source such as a laser provides light of a predefined wavelength. The laser is illuminated to an objective positioned in the light path to the diamond. A beam splitter may be a dichroic filter acting as a mirror (i.e., a dichromatic mirror) for the excitation wavelengths and is transparent to all other wavelengths.

Light emitted from the diamond (which has a wavelength spectrum above the excitation wavelength) is directed back through the beam splitter to a detector through a detection pinhole. To distinguish between NV⁻ and NV⁰ fluorescence, the light emitted from the diamond passes through a high pass filter (cut-off frequency=650 nm) or a band pass filter (575-625 nm), respectively, positioned in the optical path between the beam splitter and the detector.

In some embodiments, in a confocal arrangement, the device comprises a primary excitation source to provide coherent light emission (e.g., a laser system) through a pinhole aperture situated in a conjugate confocal plane with a scanning point on the diamond sample and a fluorescence detector (e.g., a photomultiplier tube); light emitted from the excitation source is reflected by a dichromatic mirror and scanned across the sample in a defined focal plane, fluorescence emitted from points on the sample in the same focal plane pass back through the dichromatic mirror and are focused as a confocal point at the detector pinhole aperture.

Further provided is a device arranged as a confocal device (or microscope) for determining presence of at least one radical species in a sample, the device comprising a diamond sample holder for a diamond comprising at least one or a plurality of NV centers, a primary excitation source configured and operable to excite the NV center(s), a fluorescence detector and at least one wavelength filter configured and operable to distinguish between fluorescence emission from NV-centers and fluorescence emission from NV0 centers.

In some embodiments, in the confocal device the primary excitation source is positioned to provide point-illumination of at least one or plurality of the NV centers at a preselected spot and depth; wherein
an objective is positioned between the primary source and the diamond in the light path to the diamond;
a beam splitter positioned in a light path between the diamond and the detector;
a high pass filter and/or a band pass filter are provided in an optical path between the beam splitter and the detector; and
a confocal pinhole is provided in an optical pathway to the detector to eliminate out of focus signals from being received by the detector, thereby limiting detection to fluorescence signals emitted from the illuminated point.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A-B depicts the energy level and crystallographic structure of an NV center. FIG. 1A shows Nitrogen-Vacancy in a diamond lattice. FIG. 1B represent energy level diagram. Excitation is depicted with upwardly directed arrows; fluorescence is depicted with downward red arrows. Transition between NV⁻ excited state and NV⁰ ground state is depicted with dashed arrows.

FIG. 2 provides calibration curve for hydroxyl radical formation rate. A linear increase in hTPA absorption at 310 nm was detected by TPA assay, upon irradiation on hydrogen peroxide. A linear increase was also observed as a function of the light intensity.

FIGS. 3A-C provide: (FIG. 3A) Schematic representation of the confocal setup. (FIG. 3B) Side view of the diamond covered with hydrogen peroxide. 2.5 μL hydrogen peroxide was deposited on the top of the diamond. Blue laser illuminated the hydrogen peroxide through the diamond to generate hydroxyl radicals, adjacent to the NV layer. (FIG. 3C) T1 sequence. The NVs were first polarized to the |0) ground state, and a fluorescence measurement was conducted after a delay of τ. For improved contrast, in some instances the same sequence was conducted with a microwave (MW) π pulse (flips the spin to |±1 [symbol] ) before detection.

FIG. 4 shows relaxation time (T₁) in different GdCl₃ concentrations. Relaxation time defined as the decay constant at T₁ experiment. Each dot represents relaxation time in different GdCl₃ concentration. Dashed curve is an exponential fit for the change in relaxation time as a function of GdCl₃ concentration.

FIGS. 5A-B provide: (FIG. 5A) Fluorescence sequence. The blue laser was turned on for a period τ, while the green laser was on constantly. The fluorescence was recorded during the entire experiment. (FIG. 5B) Comparison between Fluorescence sequences.

FIGS. 6A-C provide a comparison between the change in fluorescence with and without hydrogen peroxide. The average fluorescence during blue laser illumination was divided by the average fluorescence without the blue laser. (FIG. 6A) The change in fluorescence of the NV⁻ spectrum vs. blue laser power. (FIG. 6B) The change in fluorescence of the NV⁰ spectrum vs. blue laser power. (FIG. 6C) Normalized change in fluorescence, subtracting the results with a bare diamond to the results with hydrogen-peroxide, of the NV⁻ spectrum and the NV⁰ spectrum as a function of blue laser power.

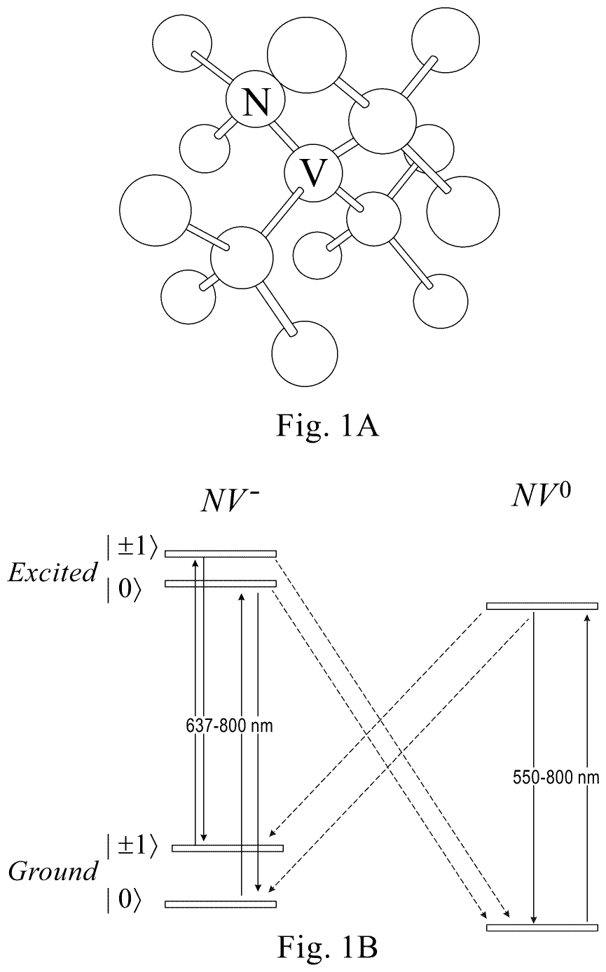

### DETAILED DESCRIPTION OF EMBODIMENTS

Diamond properties: All experiments were carried out with the same sample, grown by chemical vapor deposition (CVD, Element Six), implanted with a dose of 2×1013 15N of energy 10 KeV per atom at a 15° tilt angle. According to simulations, the mean depth of the NV layer is approximately 15 nm. The sample was then taken for an annealing session at 1200° C. for 8 hours.

Hydrogen-Peroxide: Hydrogen peroxide in 30% concentration was used. Between experiments, the diamond was cleaned with distilled water (remove remains of hydrogen peroxide) and isopropanol (Sigma Aldrich, Israel).

Gd-Chloride: 6 gr agar (Sigma Aldrich, Israel) were added to 100 ml distilled water and heated it to boil while stirring. The GdCl₃ (Sigma Aldrich, Israel) 0.037 gr is then added to a 1 ml of the agar to reach a concentration of 100 mM Gd³⁺ ions. Finally, 2.5 μl of the heated agar mixture is drop on isopropanol pre-cleaned NV surface and left to cool and solidify.

T₁ and Fluorescence sequences: All experiments were performed in a confocal microscope with an oil-immersion objective (Nikon 60×). Measurements were performed using a Swabian Instruments pulsestreamer and a National Instruments data acquisition card. In order to distinguish between NV⁻ and NV⁰ fluorescence, a high pass filter (cut-off frequency=650 nm) and a band pass filter (575-625 nm), respectively, were used.

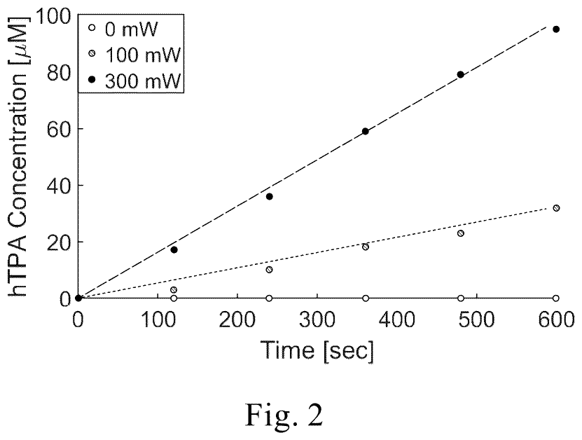

The amount of hydroxyl radicals produced upon light excitation on H₂O₂ with 405 nm laser and its dependence on the light intensity was characterized by terephthalic acid (TPA) assay. FIG. 2 shows a linear increase with the illumination time and intensity of the absorption at 310 nm, attributed to hydroxyterephthalic acid product. This allows to estimate the concentration of the radicals produced in our system to be 0.5 nM s per 1 mW cm² laser intensity.

TPA assay: Terephthalic acid solution was prepared by dissolving 1 mg/mL of TPA in KOH solution (1 mg/mL of TDW). The TPA solution (1800 uL) was mixed with 200 uL of 30% H₂O₂ in a quartz cuvette and illuminated using a 405 nm laser coupled to fiber through the vertical axis of the cuvette. The produced hydroxyl radicals attack the Terephthalic acid producing hydroxyterephthalic acid-(hTPA) product with distinct absorption at 310 nm. The change in absorption spectra with and without illumination was followed using a JASCO V-570 spectrophotometer.

For an illumination intensity of 100 mW/(cm²), the hydroxyl generation rate was 50 ±9 nM/s. Radical generation rate (G) is linear with time, thus:

$${G}_{Beer - Lambert} = 50 \frac{nM}{S} \to 5 \times {10}^{- 5} \frac{nM}{μ S} \qquad ( 1 )$$

In addition, hydroxyl generation rate was linear with illumination intensity.

$$\begin{matrix}\frac{{G}_{NV}}{{G}_{Beer - Lambert}} = \frac{{I}_{NV}}{{I}_{Beer - Lambert}} \\ = \frac{1.2 \times {10}^{7}}{100} = 1.2 \times {10}^{5}\end{matrix} \qquad ( 2 )$$

Here, the lowest intensity the signal could be distinguished was replaced, because the calculation was expected to yield the threshold concentration the NV system could measure. The generation rate in NV system was:

$${G}_{NV} = 1.2 \times {10}^{5} \times 5 \times {10}^{- 5} = 6 \pm 1 \frac{nM}{μ S} \qquad ( 3 )$$

The concentration with ODE can be described with:

$$\frac{dP ( t )}{dt} = G - P ( t ) R , \qquad ( 4 )$$

where G and R are the generation rate and depletion rate respectively, and P(t) is the concentration. In a steady state condition, the concentration is:

$$\begin{matrix}\frac{dP ( t )}{dt} = 0 \to {P}_{ss} = \frac{G}{R} [ \frac{\frac{nM}{μ S}}{μ {S}^{- 1}} ] \\ = \frac{6 \times {10}^{- 9}}{0.37} = 16 \pm 3 nM\end{matrix} \qquad ( 5 )$$

The sequence has to run 0.5 seconds to reach SNR=1, therefore the sensitivity may be calculated as follows:

$$\begin{matrix}T ( SNR = 1 ) = 0.5 sec \to η = \frac{16.21}{\sqrt{0} \text{.5}} \\ = 11 \pm 4 \frac{nM}{\sqrt{H} z}\end{matrix} \qquad ( 6 )$$

The NV layer was sensitive to radicals proximate to the surface (200×200×100 nm³) efficient volume. In terms of molecules, the sensitivity was:

$$\begin{matrix}{η}_{Particles} = η \times {N}_{a} \times V \\ = 11 \times {10}^{- 9} \times {N}_{a} \times 4 \times {10}^{- 18} \\ = 0.03 \pm 1 \times {10}^{- 2} \frac{molecules}{\sqrt{H} z}\end{matrix} , \qquad ( 7 )$$

where Na and V are the Avogadro number and the effective volume proximate to the NV surface respectively.

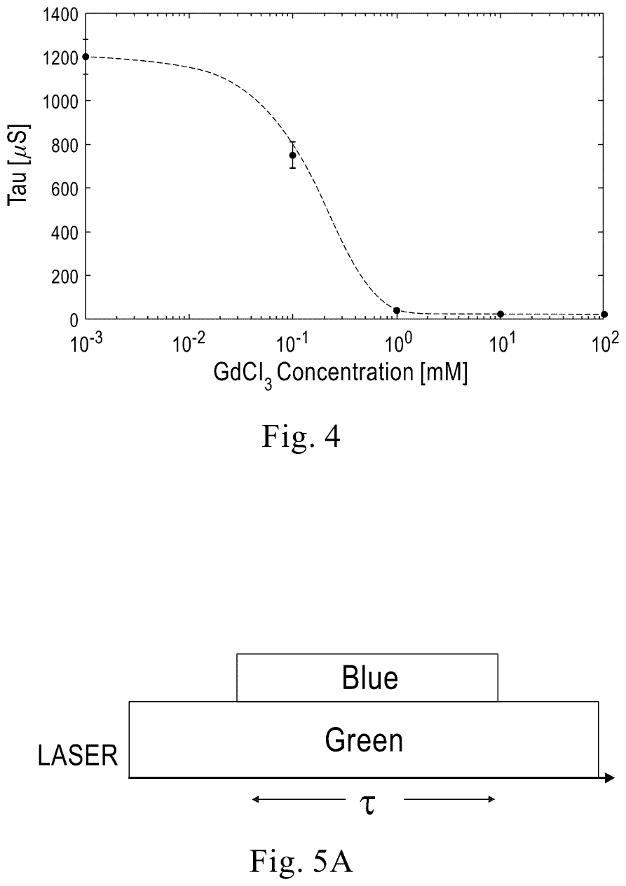

The system standard relaxometry protocols were initially implemented, studying the change in the longitudinal T₁ relaxation time of the NVs in the presence of magnetic noise from Gadolinium (III) chloride (GdCl₃) as a function of concentration. The Gadolinium(III) chloride was mixed with Agar, forming a solid matrix with uniform GdCl₃ concentration. Subsequently, the mixture was deposited on the top of the diamond. The results are summarized in FIG. 4, depicting the dependence of the measured T₁ relaxation time on the Gd concentration. Comparing to previously published work we find that our sensitivity, which is limited to a concentration of approximately 100 μM, slightly exceeds the state-of the-art and indicates an appropriate experimental setup and diamond sample.

This approach, however, is hindered by the measurement timescale (corresponding to the T₁ relaxation time, on the order of ms), which is long compared to the ROS lifetime. This could potentially lead to variations in the ROS concentrations during the measurement time. In addition, these experiments have limited Signal to Noise ratio (SNR).

In the following, a faster scheme is introduced which is based on NV fluorescence changes resulting from quenching induced by the radicals.

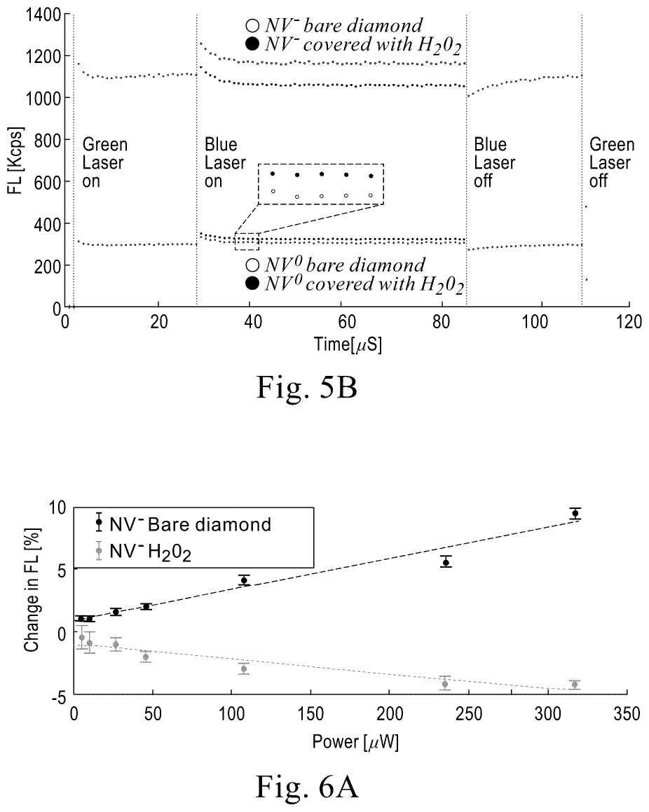

FIG. 5A presents the experimental protocol for fluorescence measurements. In these experiments, radicals were generated by illuminating hydrogen-peroxide with a blue laser (405 nm). This induces a photo-chemical process which decomposes the H₂O₂ molecule to form two Hydroxyl radicals. This allows to controllably create radicals at a desired rate, corresponding to the intensity of the blue light. Specifically, the fluorescence change induced by the radicals (FL) can be measured in situ, compared to the fluorescence of the baseline value, obtained with the same sequence for bare diamond. The change in fluorescence was calculated as follows:

$$change in FL = \frac{average FL with blue laser}{average FL without blue laser}$$

FIG. 5B depicts measured fluorescence during the sequence as a function of time. These measurements were performed by extracting the change in fluorescence of both NV⁻ and NV⁰ with ROS and for bare diamond. As one may observe, as the blue laser is turned on and off, a transient of <10 μs precedes the steady-state fluorescence value.

It should be noted that the blue laser (405 nm) used to generate radicals, causes an increase of the fluorescence intensity in both NV⁻ and NV⁰ spectra (FIG. 5B). This is consistent with the excitation of the NV centers by both green and blue lasers. Therefore, the added excitation leads to a higher population in the NV excited state which can decay radiatively.

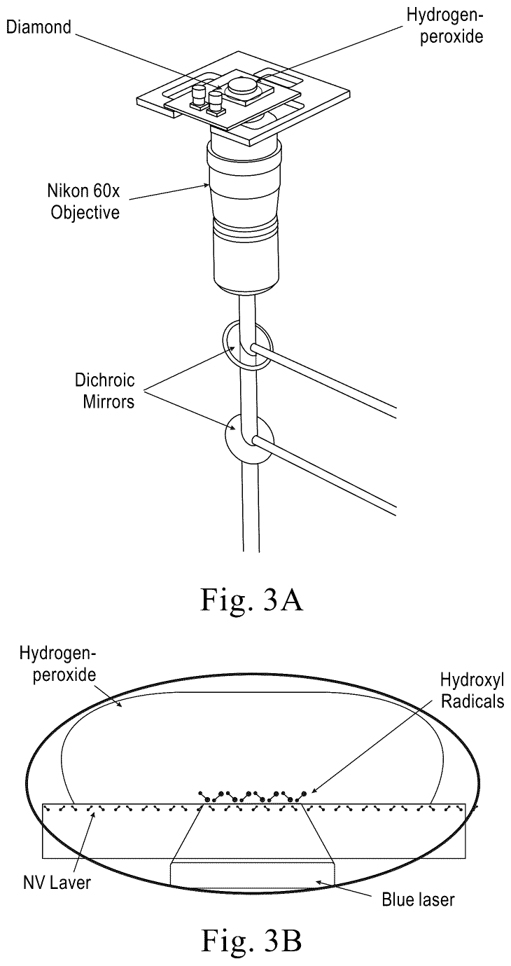

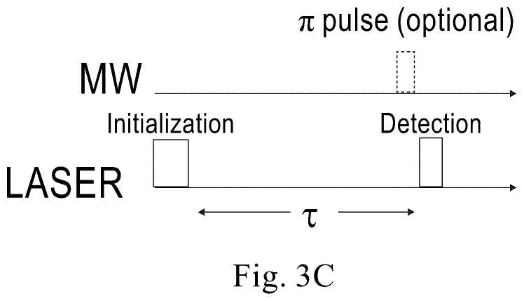

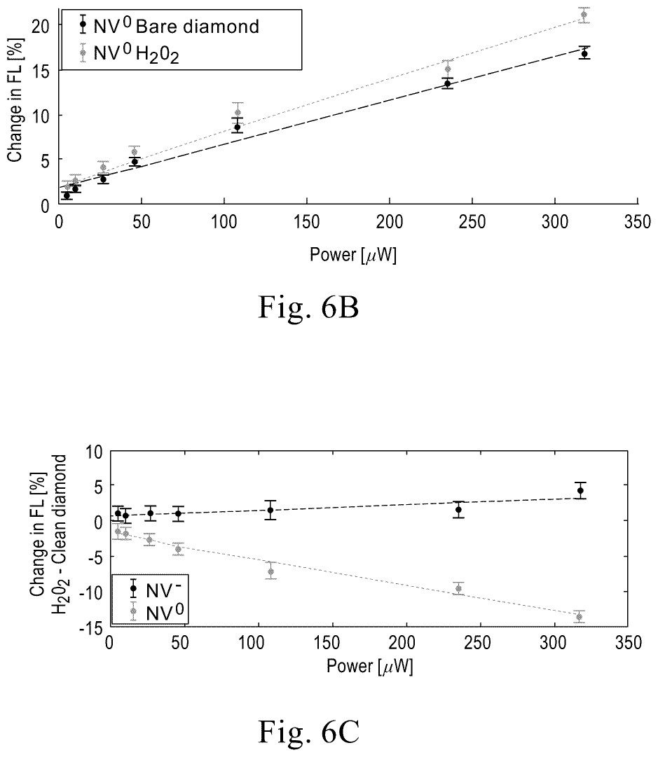

FIG. 6 shows the steady-state change in normalized fluorescence (FL) as a function of radical concentration (controlled by the intensity of the applied blue light). In this set of experiments 2.5 μL of Hydrogen-Peroxide (H₂O₂, concentration=30%) covered the top of the diamond (FIG. 3B). Upon increasing the blue laser power, a drop in NV⁻ fluorescence is seen (FIG. 6A), accompanied by an increase in the NV⁰ fluorescence (FIG. 6B). FIG. 6C presents the normalized fluorescence change with respect to the bare diamond results as a function of blue light intensity, clearly showing the increased NV⁰ fluorescence concurrently with the drop in NV⁻ fluorescence.

Calibrating the blue illumination intensity to ROS concentration, this fluorescence change can be translated to radical concentration sensitivity.

As mentioned above, the blue laser decomposes the H₂O₂ molecule and forms hydroxyl radicals which are highly reactive. Thus, a redox reaction occurs between the NV (undergoes oxidation) and the radicals. This process is consistent with the rise in NV⁰ fluorescence at the expense of NV⁻ fluorescence (FIG. 6). To translate the blue laser intensity to hydroxyl concentration, a calibrated Beer-Lambert absorption experiment was conducted. These measurements indicate that at threshold illumination (5 μW) the steady-state Hydroxyl concentration is 16 nM. Given this calibration, it may be deduced

that NV fluorescence measurement sensitivity to radical concentration is

$${11}^{\pm 4 \frac{nM}{\sqrt{H} z}} .$$

It should be noted that the NV system allows localized, small volume measurements, down to ˜10 picoliter in our experiment (for which the molar concentration sensitivity may be translated to an effective number of molecules, which is found to be much smaller than 1, i.e.,

$$0.03 \pm 0.01 \frac{Particles}{\sqrt{Hz}} .$$

1.-59. (canceled)

60. A non-magnetic method for determining presence and/or concentration of at least one radical species in a sample, the method comprising exciting at least one nitrogen vacancy (NV) center in a diamond having at least one near-surface NV center, while the diamond is in contact with a sample containing or suspected of containing the at least one radical species and measuring fluorescence emitted from the at least one NV center in response to said excitation, wherein the NV center comprises neutral NV⁰ states and negative NV⁻ states, such that the presence of the at least one radical species causes a decrease in a fluorescence rate of the NV⁻ states and an increase in a fluorescence rate of the NV⁰ states.

61. The method according to claim 60, wherein the change in the emission rate is determined by:
measuring the rate of fluorescence emitted from the diamond NV center(s) comprising NV⁻ and NV⁰ centers following excitation and prior to contacting the diamond NV center(s) with the sample containing or suspected of containing the at least one radical species;
measuring the rate of fluorescence emitted from the diamond NV center(s) comprising NV⁻ and NV⁰ centers following excitation and after contacting the diamond NV center(s) with the sample containing or suspected of containing at least one radical species; and
determining the change in the NV⁻ fluorescence emission rate and/or the NV⁰ fluorescence emission rate;
wherein a decrease in the NV⁻ fluorescence emission rate and/or an increase in the NV⁰ fluorescence emission rate provides an indication of presence of the at least one radical species in the sample.

62. The method according to claim 60, wherein measuring the rate of fluorescence emitted from the diamond NV center(s) prior to or after contacting with the sample comprises measuring a rate of emission from the NV⁻ centers and/or measuring rate of emission from the NV⁰ centers.

63. The method according to claim 60, wherein the exciting or irradiating comprises use of an excitation source.

64. The method according to claim 63, wherein the excitation source is a light source.

65. The method according to claim 60, wherein the exciting or irradiating comprises illuminating the diamond with a light having a wavelength between 380 and 638 nm, or between 380 and 480 nm.

66. The method according to claim 63, wherein the exciting or irradiating comprises an excitation source comprising at least two illumination sources.

67. The method according to claim 66, wherein each of the at least two illumination sources is configured to independently generate light of a wavelength between 380 and 638 nm.

68. The method according to claim 60, wherein the exciting or irradiating comprises illumination by green light and/or blue light.

69. The method according to claim 68, wherein blue laser illumination is over a period of time shorter than the time period of the green laser illumination.

70. The method according to claim 68, wherein illumination comprises illumination by a green laser for a period of time and simultaneous illumination with a blue laser for a shorter period of time.

71. The method according to claim 60, the method comprising
irradiating the diamond with a green laser for a period of time;
irradiating the diamond with a blue laser while irradiation with a green laser continues;
ceasing irradiation with the blue laser and measuring fluorescence emission for a time period from the ceasing of the irradiation with the blue laser, while irradiation with the green laser continues.

72. The method according to claim 60, for qualitatively or quantitatively determining presence of the radical species in the sample for studying radical related degradation; for providing mapping and tracking of radical-mediated intracellular signal transduction and cellular signaling; or for providing information on an origin, propagation and functioning of radicals in a sample.

73. A device comprising a diamond sample holder for a diamond comprising at least one or a plurality of NV centers, a primary excitation source configured and operable to excite the NV center(s), a fluorescence detector and optionally at least one wavelength filter configured and operable to distinguish between fluorescence emission from NV⁻ centers and fluorescence emission from NV⁰ centers, wherein the NV center comprises neutral NV⁰ states and negative NV⁻ states, such that the presence of the at least one radical species causes a decrease in a fluorescence rate of the NV⁻ states and an increase a fluorescence rate of the NV0 states.

74. The device according to claim 73, wherein the device comprises:
the diamond sample holder,
the primary excitation source,
the fluorescence detector, and
the at least one wavelength filter configured and operable to distinguish between fluorescence emission from NV⁻ centers and fluorescence emission from NV⁰ centers.

75. The device according to claim 73, wherein the primary excitation source is a light source configured for illuminating the diamond sample at a preselected wavelength.

76. The device according to claim 73, wherein detection is via a pinhole provided in an optical conjugate plane in front of the detector to eliminate out-of-focus emission signals.

77. The device according to claim 73, comprising a high pass filter having a cut-off frequency at 650 nm and/or a band pass filter having a cut-off frequency at 575-625 nm, positioned in an optical path between the beam splitter and the detector.

78. The device according to claim 73, for detecting presence and/or concentration of at least one radical species in a sample, wherein a surface region of the diamond sample having at least one near-surface nitrogen vacancy (NV) center contacted by a sample comprising or suspected of comprising at least one radical species is excited by the primary radiation and fluorescence emission is detected from the diamond.

79. A device arranged as a confocal device for determining presence of at least one radical species in a sample, the device comprising a diamond sample holder for a diamond comprising at least one or a plurality of NV centers, a primary excitation source configured and operable to excite the NV center(s), a fluorescence detector and at least one wavelength filter configured and operable to distinguish between fluorescence emission from NV⁻ centers and fluorescence emission from NV⁰ centers.
